(19) United States
(12) Patent Application Publication
(10) Pub. No.: US 2026/0085417 A1
(43) Pub. Date: Mar. 26, 2026

(54) GAS-PHASE CHEMICAL REACTOR AND METHOD OF USING SAME

(71) Applicant: ASM IP Holding B.V., Almere (NL)

(72) Inventor: Antti Juhani Niskanen, Helsinki (FI)

(21) Appl. No.: 19/410,038

(22) Filed: Dec. 5, 2025

Related U.S. Application Data
(62) Division of application No. 17/682,058, filed on Feb. 28, 2022, now Pat. No. 12,516,413.
Application No. 17/682,058 is a continuation of application No. 16/004,041, filed on Jun. 8, 2018, now Pat. No. 11,286,562.

(51) Int. Cl. C23C 16/455; C23C 16/44; C23C 16/52; C23C 16/54; H01J 37/32

(52) U.S. Cl. CPC C23C 16/45544; C23C 16/4401; C23C 16/4412; C23C 16/45502; C23C 16/45536; C23C 16/52; C23C 16/54; H01J 37/32449; H01J 37/32477; H01J 37/32743; H01J 37/32788; H01J 2237/332

(57) ABSTRACT

A gas-phase chemical reactor, a system including the reactor, and methods of using the reactor and system are disclosed. An exemplary reactor includes a reaction chamber and is configured to provide a precursor within the reaction chamber for a soak period—e.g., a period wherein a supply of the precursor to the reaction chamber is ceased and before purging of the reaction chamber begins. This allows relatively high residence times, relatively high partial pressures of the precursor(s) and/or a relatively high absolute pressure to be obtained within the reaction chamber during substrate processing.

### CROSS-REFERENCE TO RELATED APPLICATIONS

This application is a divisional of, and claims priority to, U.S. patent application Ser. No. 17/682,058 filed Feb. 28, 2022 titled GAS-PHASE CHEMICAL REACTOR AND METHOD OF USING SAME; which is a continuation of U.S. patent application Ser. No. 16/004,041 filed Jun. 8, 2018 titled GAS-PHASE CHEMICAL REACTOR AND METHOD OF USING SAME (now U.S. Pat. No. 11,286,562 issued Mar. 29, 2022), the disclosures of which are hereby incorporated by reference in their entirety.

### FIELD OF INVENTION

The disclosure generally relates to gas-phase apparatus and processes. More particularly, exemplary embodiments of the present disclosure relate to gas-phase chemical reactors suitable for precursor soak applications, systems including such reactors, and to methods of using the reactors and systems.

### BACKGROUND OF THE DISCLOSURE

Gas-phase chemical reactors can be used for a variety of applications, such as for depositing and/or etching material on a surface of a substrate. A typical gas-phase chemical reactor includes a reaction chamber, a gate-valve that opens to receive a substrate and closes during substrate processing, and one or more gas sources coupled to the reaction chamber.

During substrate processing, one or more precursors flow into the reaction chamber to deposit material onto a substrate surface and/or to react with material on the substrate surface to etch the material. Generally, during substrate processing, the flow of the gas(es) reaches steady state and is continuous; i.e., after a period of time, as the gas is introduced into the reaction chamber, unreacted gasses and any gaseous byproducts are continuously removed from the reaction chamber.

By way of examples, during a typical atomic layer deposition (ALD) process, a first precursor is provided to the reaction chamber in a continuous manner for a period of time or a step, such that unreacted first precursor and/or any gaseous byproducts of the first precursor are removed during the step. This facilitates the precursor flowing across a surface of the substrate during the step. The substrate is then exposed to a reduced pressure and/or a purge gas to further remove any excess precursors and/or byproducts during a purge step. These steps can be repeated as desired for the same and/or additional precursors until a film of desired thickness is obtained.

While such technique works relatively well for some applications, for other applications, continuously flowing one or more precursors during substrate processing can result in undesired waste of unreacted precursors, undesirably long substrate process times, and/or films with undesirable properties. Further, using such techniques, it may be difficult to obtain desired concentrations, partial pressures and/or absolute reaction chamber pressures desired to drive some reactions. For example, in some ALD processes (e.g., using SAM.24 (Air Liquide)) as a silicon precursor, a precursor can reach an initial growth-rate saturation level quickly, but the precursor may not reach full growth-rate saturation at typical precursor partial pressures, even with relatively long pulse times; thus a growth rate of a deposited film may be lower than desired. In other processes, relatively high concentrations/partial pressures of one or more precursors are desired to drive the reaction at a desired rate (e.g., for the deposition of TiN from TiCl₄ and NH₃, the NH₃ desirably has a relatively high concentration or partial pressure to drive the film-forming reaction to completion before by-product formation generates undesired/poisoning species). Such high partial pressures can be difficult to achieve with typical reactors. Additionally, formation of self-assembled monolayers can require relatively long exposure times and/or relatively high precursor concentrations/partial pressures to achieve desired film properties, and such conditions can be difficult to obtain with typical reactors. Furthermore, chemical gas-phase reactors often employ relatively expensive gas-distribution apparatus to uniformly distribute gas across a substrate surface; such designs may be desired when the precursor(s) continuously flow across a substrate surface. Accordingly, improved apparatus and methods for gas-phase chemical processing are desired.

Any discussion of problems provided in this section has been included in this disclosure solely for the purposes of providing a context for the present invention, and should not be taken as an admission that any or all of the discussion was known at the time the invention was made.

### SUMMARY OF THE DISCLOSURE

Various embodiments of the present disclosure provide an apparatus and a method that can provide extended residence time, partial pressure, and/or absolute pressure of one or more precursors within a reaction chamber of a gas-phase chemical reactor. As set forth in more detail below, various systems and methods allow for relatively less precursor usage and waste, compared to traditional apparatus and methods, which can reduce costs associated with processing substrates. Exemplary systems and methods can also facilitate high growth rates and/or driving of reactions that might otherwise not take place. Additionally or alternatively, exemplary embodiments can provide for relatively rapid pumping/evacuation of gas from a reaction region or chamber within the gas-phase chemical reactor. Further, some exemplary systems and methods do not require use of relatively expensive gas distribution apparatus to achieve desired process uniformity.

In accordance with at least one exemplary embodiment of the disclosure, a gas-phase chemical reactor includes a reaction chamber for processing a substrate; a load/unload chamber comprising an opening to receive the substrate and a valve (e.g. gate valve) to seal the opening; a susceptor having a top surface to receive the substrate, wherein the susceptor is moveable within the load/unload chamber, and wherein a top surface of the susceptor defines at least a portion of a bottom section of the reaction chamber when the substrate is in a processing position and a vacuum source for evacuating the load/unload chamber. The gas-phase chemical reactor can further include a controller to, for example, control a precursor delivery process and an evacuation process. The controller comprising a memory being programmed to enable the controller to execute the following steps: while the susceptor is in the processing position, providing a precursor to the reaction chamber, while evacuating the load/unload chamber; ceasing a flow of the precursor, and evacuating the reaction chamber by moving the susceptor into the load/unload chamber. Additionally, the gas-phase chemical reactor can include a protective shield (e.g., a plate) to protect the valve. The protective shield can be attached to the valve. In accordance with various aspects of these embodiments, the protective shield extends beyond at least a top surface of the gate valve. In accordance with further exemplary aspects, the gas-phase chemical reactor includes an inert gas source, wherein an inert gas from the inert gas source is provided between an interior wall of the load/unload chamber and a surface of the protective shield. The gas-phase chemical reactor can also include a movable shaft coupled to the susceptor. In these cases, the gas-phase chemical reactor can include a protective cover (e.g., a bellows) about at least a portion of the moveable shaft and a shaft opening within a bottom of the load/unload chamber. As discussed in more detail below, in accordance with various examples, volumes of the reaction and load/unload chambers can be configured to facilitate rapid pumping of the reaction chamber. For example, the volumetric ratio of the reaction chamber interior volume to the load/unload chamber interior volume can range from about 1:5 to about 1:160, about 1:10 to about 1:80, or about 1:20 to about 1:60. Gas-phase chemical reactors described herein can include a showerhead gas distribution apparatus. In at least some cases, exemplary gas-phase chemical reactors may not include a showerhead gas distribution or similar apparatus, and may therefore be less complex and/or less expensive than other gas-phase chemical reactors. In accordance with additional aspects, a gas-phase chemical reactor includes a guide to direct flow of gas from the reaction chamber to the load/unload chamber—e.g., during a purge step. The guide can be further configured to mitigate gasses from the reaction chamber contacting walls of the load/unload chamber. In these cases, the gas-phase chemical reactor may not include the protective shield.

In accordance with additional exemplary embodiments of the disclosure, a system includes a gas-phase chemical reactor, such as a gas-phase chemical reactor described herein, and one or more other components, such as a vacuum source, one or more precursor sources, one or more purge gas sources, one or more carrier gas sources, a transfer or robotic arm, and the like.

In accordance with yet further exemplary embodiments of the disclosure, a method (e.g., for processing a substrate) includes the steps of moving a susceptor from a load/unload position to a processing position; while the susceptor is in the processing position, providing a precursor to the reaction chamber, (e.g., while evacuating the load unload chamber by providing vacuum to or maintaining a vacuum within the load/unload chamber); ceasing a flow of the precursor, and moving the susceptor into the load/unload chamber. When the substrate is moved to the load/unload chamber, the substrate can be exposed to a second pressure—e.g., that is lower than the first pressure. The method can further include a step of opening a valve to receive the substrate, closing the valve to seal the opening and/or protecting the valve with a protective shield. Additionally or alternatively, the method can include providing a carrier gas during all or a portion of the step of providing a precursor.

Both the foregoing summary and the following detailed description are exemplary and explanatory only and are not restrictive of the disclosure or the claimed invention.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a system including a gas-phase chemical reactor in a load/unload position in accordance with at least one embodiment of the disclosure.

FIG. 2 illustrates a system including a gas-phase chemical reactor in a processing position in accordance with at least one embodiment of the disclosure.

FIG. 3 illustrates a portion of a system including a gas-phase chemical reactor in a purge position in accordance with at least one embodiment of the disclosure.

FIG. 4 illustrates a valve and a protective shield in accordance with at least one embodiment of the disclosure.

FIG. 5 illustrates a method in accordance with at least one embodiment of the disclosure.

FIG. 6 illustrates a pressure diagram in accordance with at least one embodiment of the disclosure.

FIG. 7 illustrates a portion of another system including a gas-phase chemical reactor in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help to improve understanding of illustrated embodiments of the present disclosure.

### DETAILED DESCRIPTION OF EXEMPLARY EMBODIMENTS OF THE INVENTION

The description of exemplary embodiments of reactors, systems, and methods provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

Any ranges indicated in this disclosure may include or exclude the endpoints. Additionally, any values of variables indicated (regardless of whether they are indicated with “about” or not) may refer to precise values or approximate values and include equivalents, and may refer to average, median, representative, majority, or the like.

As used herein, precursor references to one or more gasses that take part in a chemical reaction. The chemical reaction can take place in the gas phase and/or between a gas phase and a surface of a substrate and/or a species on a surface of a substrate.

The systems, reactors, and methods described herein can be used for a variety of applications in which, for example, relatively high concentration, relatively high partial pressure, and/or relatively high residence time of one or more gasses, such as one or more precursors, within a reaction chamber is desired; mitigation of precursor waste that might otherwise occur is desired; and/or relatively high absolute pressure within the reaction chamber is desired. By way of examples, exemplary systems, reactors, and methods can be used in atomic layer deposition (ALD) applications in which increased partial pressure and/or concentration of one or more precursors is desired, such as when precursors reach a soft growth rate saturation using typical ALD processing techniques (e.g., use of SAM.24 precursor with an oxygen plasma); in ALD reactions in which high partial pressure is desired to drive a film-forming process and/or to mitigate undesired byproduct formation/poisoning—e.g., ALD deposition of TiN using TiCl₄ and NH₃; in reactions (e.g., single precursor reactions) where high partial pressure of a precursor is desired-such as during formation of self-assembled monolayers; and conventional ALD processes (e.g., formation of aluminum oxide from trimethylaluminum (TMA) and an oxidant, such as water), where relatively expensive gas distribution apparatus (e.g., a showerhead) is often used to distribute one or more precursors across a surface of a substrate. Although the systems, reactors, and methods are described below in the context of ALD reactors, unless otherwise noted, the systems, reactors, and methods are not so limited.

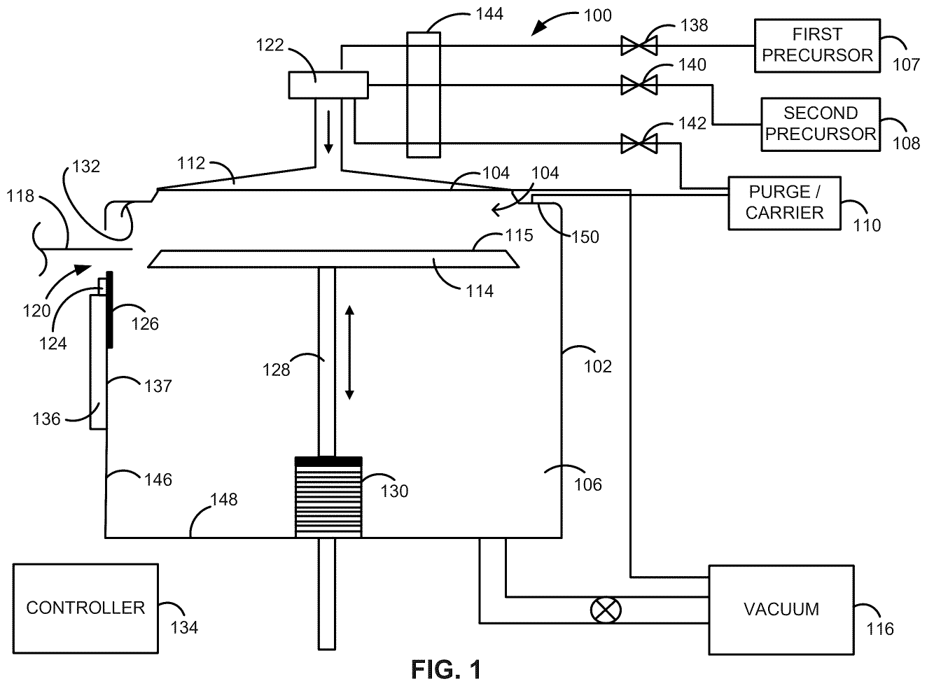

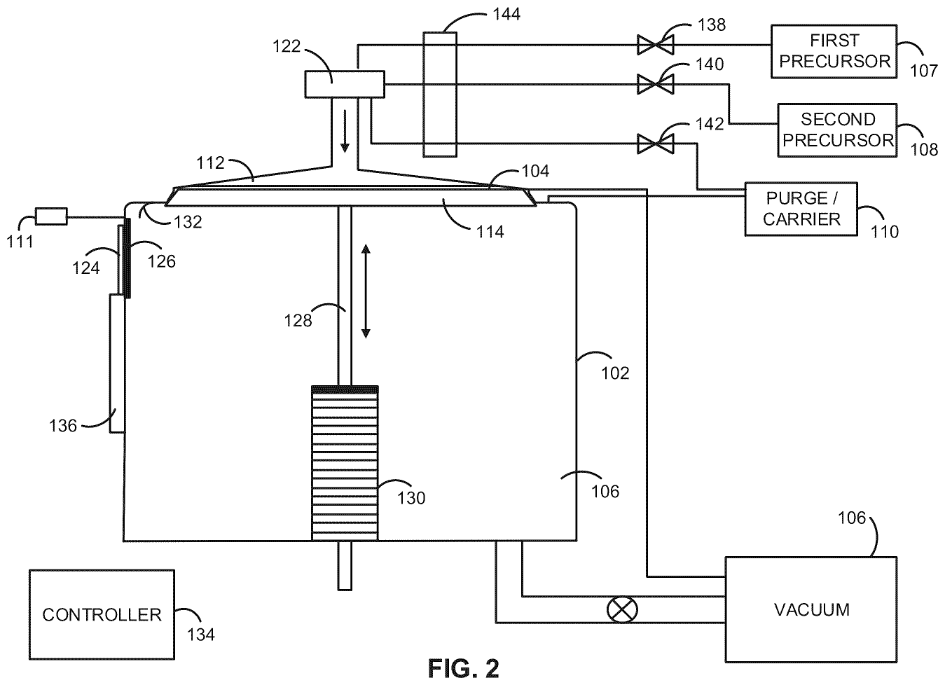

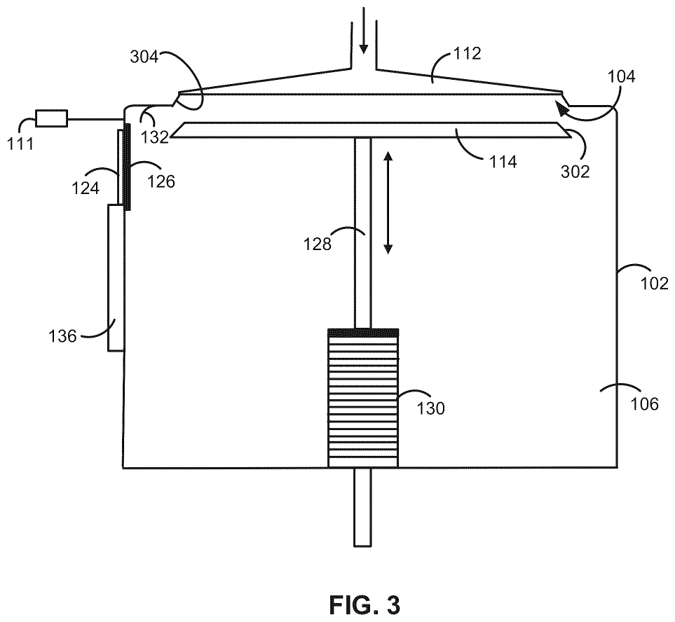

Turning now to the figures, FIGS. 1-3 illustrate a system 100 in accordance with at least one embodiment of the disclosure. FIG. 1 illustrates system 100 in a load/unload position. FIG. 2 illustrates system 100 in a processing position. FIG. 3 illustrates a portion of system 100 in a purge position.

System 100 includes a gas-phase chemical reactor 102, including a reaction chamber 104 and a load/unload chamber 106, a first precursor source 107, a second precursor source 108, a purge gas source 110, a gas distribution apparatus 112, a susceptor 114, a vacuum source 116, and a controller 134. System 100 also includes a valve (e.g., a gate valve) 124 to seal an opening 120 within load/unload chamber 106 and a protective shield 126 to protect valve 124 from exposure to processing gasses used within reaction chamber 104 and purged through load/unload chamber 106. A valve actuator 136, which can be coupled to controller 134, can be used to cause valve 124 to open and close. System 100 can optionally include a remote plasma unit 144 to activate one or more gasses precursor sources 1-7, 1-8 and/or purge/carrier source 110. Additionally or alternatively, system 100 can include a direct plasma system, where, for example, susceptor 144 or a portion thereof forms an electrode of a direct plasma apparatus, gas distribution apparatus 112 can form another electrode, and/or system 100 can include an inductively-coupled plasma apparatus.

As described in more detail below, during operation of system 100, a substrate (not illustrated) can be transferred to susceptor 114 within load/unload chamber 106 through opening 120 and moved to reaction chamber 104 (e.g., using a shaft 128). During the processing period, reaction chamber 104 can be isolated from load/unload chamber 106, and the substrate can be exposed to one or more precursors (e.g., from sources 107, 108) within reaction chamber 104, while a vacuum (e.g., lower pressure than the pressure in reaction chamber 104) is maintained within load/unload chamber 106. As used herein, the term isolated and does not require a complete seal, but can also include a substantial seal and/or a tortuous path between reaction chamber 104 and load/unload chamber 106, such that gasses from precursor sources 107, 108 do not continuously flow through reaction chamber 104, but rather, an amount of the precursors continues to rise for a period of time and can remain substantially constant (e.g., within ten percent, five percent, or one percent of a peak value, minus any reduction due to chemical reactions, within reaction chamber 104) during a soak period. The substrate can remain within reaction chamber 104 while the precursor(s) are introduced into the reaction chamber 104 and for the soak period. As used herein, a soak period refers to a period of time after a flow of gas from a precursor source is ceased, while reaction chamber 104 is isolated from load/unload chamber 106, such that the substrate remains in contact with the precursor within reaction chamber 104 for a period of time after the precursor flow is turn off. At the end of the soak period, the substrate is lowered into load/unload chamber 106. At this time, reaction chamber 104 can be evacuated using the pressure differential between reaction chamber 104 and load/unload chamber 106 and/or a vacuum provided by a vacuum source 116. A purge gas (e.g., from purge gas source 110) can optionally be provided to further facilitate purging of any unreacted precursor(s) and/or byproducts. These steps can be repeated for the same or different precursors until a desired film is formed on a surface of the substrate.

With reference again to FIG. 1, reactor 102 can be formed of, for example, stainless steel, titanium and/or aluminum, or the like. Further, reactor 102 can be a standalone reactor or form part of a cluster tool that may include similar or different reaction chambers. In accordance with exemplary embodiments of the disclosure, reaction chamber 104 is relatively small (e.g., for processing a substrate having a diameter of about 300 mm, an interior volume of reaction chamber 104 can be about 0.5 to about 1 or about 0.7 dm³). The relatively small interior volume allows for high partial and/or absolute pressures to be rapidly reached, using a relatively small amount of precursor, which in turn facilitates rapid, inexpensive processing of substrates. In accordance with further examples, an interior volumetric ratio of the interior volume of load/unload chamber 106 to the interior volume of reaction chamber 104 can be relatively high. For example, the volumetric ratio of the interior volume of load/unload chamber 106 to the interior volume of reaction chamber 104 can range from about 5:1 to about 160:1, about 10:1 to about 80:1, or about 20:1 to about 60:1, or be greater than 5, 60, or 160. The relatively high volumetric ratios allow for rapid purging of reaction chamber 104, when load/unload chamber 106 is maintained at a lower pressure than reaction chamber 104, which in turn, facilitates rapid processing of the substrates.

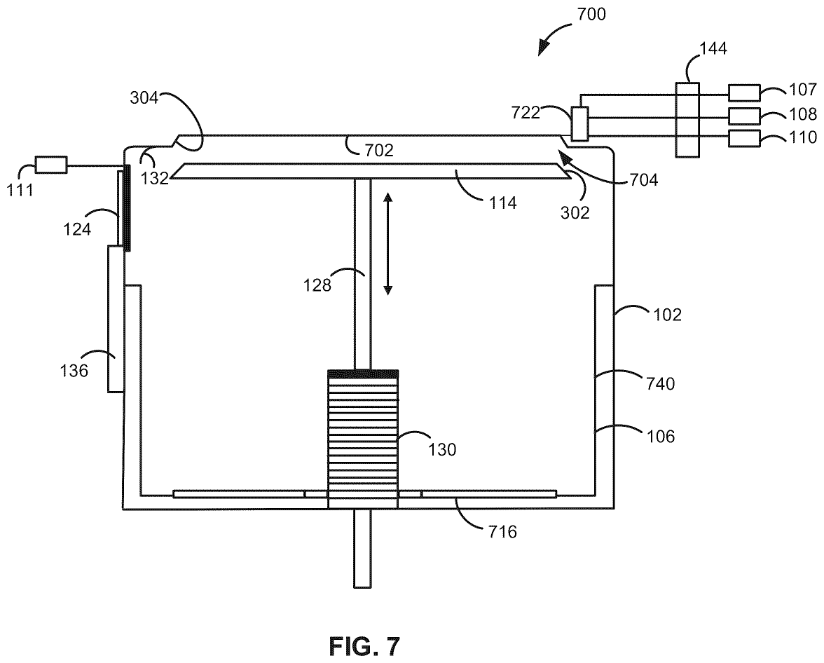

In accordance with some examples of the disclosure, load/unload chamber 106 can be of relatively simple design—e.g., a bottom portion (e.g., a portion of load/unload chamber below where the gate is attached to actuator 136) can have a shape of a substantially hollow cylinder having a bottom. This allows the bottom portion to be easily removed and replaced and/or cleaned. Additionally or alternatively, system 100 can include a removable (e.g., disposable) liner, as illustrated in FIG. 7. Additionally or alternatively, load/unload chamber 106 can include a purge gas inlet near the interface with reaction chamber 104. To further facilitate purging of any reactants and to mitigate contact of the reactants with an interior surface of load/unload chamber 106. Walls of load/unload chamber 106—e.g., one or more of walls 146, 148, and/or 150 can be heated (e.g., to a temperature above a condensation temperature of the precursors and/or any reaction byproducts) to mitigate any condensation thereon.

First and second precursor sources 107, 108 can include any suitable substance for a gas-phase reaction. The precursors within sources 107, 108 may initially be solid, liquid or gas. In the case of solids and liquids, the precursor can be transformed into a gas state by heating, using bubblers, or the like.

Purge/carrier gas source 110 can include any suitable gas or material that becomes gas that is capable of purging reaction chamber 104 and/or that is suitable as a carrier gas. Exemplary purge and/or carrier gasses include argon, nitrogen, and/or hydrogen. When a carrier gas is provided, the carrier gas can be mixed with one or more gasses—e.g., from first precursor source 107 and/or second precursor source 108 at and/or before mixer 122. Although system 100 is illustrated with two precursor sources and one purge/carrier gas source, system 100 can include any suitable number of precursor sources, purge gas sources, and/or carrier gas sources and, in some cases, need not include a purge gas source and/or carrier gas source. Further, although illustrated as coupled to gas distribution apparatus 112, purge gas source 110 or another purge gas source can be additionally or alternatively coupled to load/unload chamber 106—directly to purge load/unload chamber 106 and/or for use as a gas curtain, describe below.

Gas distribution apparatus 112 may be configured to provide vertical (as illustrated) or horizontal flow of gasses to reaction chamber 104. An exemplary gas mixture and gas distribution apparatus is described in U.S. Pat. No. 8,152,922 to Schmidt et al., issued Apr. 10, 2012, entitled “Gas Mixer and Manifold Assembly for ALD Reactor,” the contents of which are hereby incorporated herein by reference, to the extent the contents do not conflict with the present disclosure. By way of example, gas distribution apparatus 112 may include a showerhead. However, in accordance with other embodiments, gas distribution apparatus 112 need not include a showerhead, but rather may include a relatively simple gas inlet.

Susceptor 114 can be formed of, for example, SiC or SiC-coated graphite. In accordance with some examples of the disclosure, susceptor 114 can include apertures to allow lift pins to retract into susceptor 114 during processing and protrude above a top surface 115 of susceptor 114 during a substrate transfer process. An exemplary susceptor and lift pin mechanism are disclosed in U.S. application Ser. No. 15/672,096, entitled “SUBSTRATE LIFT MECHANISM AND REACTOR INCLUDING SAME,” the contents of which are hereby incorporated herein by reference, to the extent such contents do not conflict with the present disclosure.

Vacuum source 116 can include any suitable vacuum source capable of providing a desired pressure in reaction chamber 104. Vacuum source 116 can include, for example, a dry vacuum pump alone or in combination with a turbo molecular pump. In accordance with various examples of the disclosure, vacuum source 116 is configured to provide a pressure within reactor 102, and particularly load/unload chamber 106 of about 1 to about 10⁻⁶, about 0.1 to about 10⁻⁴, or about 10⁻² to about 10⁻³ Torr. One or more vacuum sources 116 can be coupled to reaction chamber 104 and/or load/unload chamber 106.

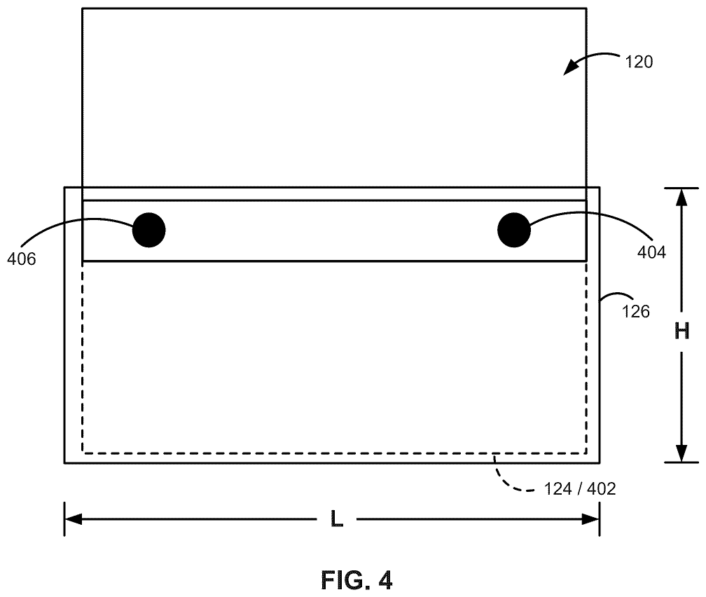

Valve 124 can include any suitable valve, such as a gate valve, to seal opening 120 within load/unload chamber 106. In accordance with exemplary embodiments of the disclosure, valve 124 is a gate valve comprising a plate 402, illustrated in FIG. 4. Valve 124 can be caused to open or close (e.g., move up or down), using actuator 136, which can be coupled to controller 134.

Protective shield 126 can be used to protect valve 124 from reactive species as the species are purged from reaction chamber 104 to load/unload chamber 106. Protective shield 126 can be formed of, for example, stainless steel, titanium or aluminum, having dimensions that are slightly (e.g., about 2%, 5%, 10%, 15%, or 20%) larger in heights (H) and/or length (L) than valve 124. As illustrated in FIG. 4, protective shield 126 can be fixedly or removably attached to vale 124 using one or more fasteners 404, 406, which can be or include, for example, welds, bolts, screws, or the like. Alternatively, valve 124 and protective shield 126 can be of unitary construction. To further protect valve 124, a flow (e.g., 25 to 100 sccm) of inert gas (e.g., nitrogen, argon, or the like) can be provided between valve 124 and/or an interior wall 137 of reactor 102/load/unload chamber 106 and protective shield 126 to form a gas curtain that prevents or mitigates gas from reaction chamber 104 reaching valve 124 during a purge process. Further, protective shield 126 can be configured, such that protective shield 126 does not touch an interior wall of the load/unload chamber 106, when protective shield 126 moves. Alternatively, protective shield 126 can be configured, such that protective shield 126 forms a hard seal on the top-most interior surface of the load/unload chamber 106 (e.g., above opening 120) when the valve 124 is closed, partly or completely, mitigating the need for sealing gas flow.

Shaft 128 can be configured to move up and down to facilitate loading and unloading of a substrate through opening 120 and moving the substrate to a processing position within reaction chamber 104. In some embodiments, shaft 128 can also rotate during substrate processing and/or during a substrate load/unload operation; however, in some examples, it may not be necessary or desired to rotate shaft 128. Shaft 128 can also receive and retain various wiring—e.g., for heaters embedded and/or attached to susceptor 114, thermocouples, and the like. Although system 100 is described in connection with a shaft moving up and down, in accordance with other exemplary embodiments of the disclosure, a susceptor can move horizontally between a load/unload chamber and a reaction chamber or the susceptor could remain stationary and the reaction chamber and/or load/unload chamber could move in relation to the susceptor.

In the illustrated example, system 100 also includes a protective cover 130 (e.g., a bellows) to seal shaft 128 and load/unload chamber 106 from an environment exterior to reactor 102 and to protect a portion of the shaft and/or components attached thereto) from exposure to chemicals.

System 100 can also include a guide 132 to direct flow of gas from reaction chamber 104 to load/unload chamber 106 and away from valve 120 during a purge process. Guide 132 can be formed of, for example, stainless steel, titanium or aluminum and include a slanted or curved surface to direct the flow of gas from reaction chamber 104 away from valve 124.

Controller 134 can be coupled to one or more of shaft 128, valve actuator 136 and/or valves 138-142, to mass flow controllers coupled to one or more of first precursor source 107, second precursor source 108, and purge/carrier source 110, and the like to perform various steps as described herein. For example, controller 134 can comprise a memory being programmed to enable controller 134 to execute the following steps:
while the susceptor is in the processing position,
providing a precursor to the reaction chamber, while evacuating the load/unload chamber with the vacuum source;
ceasing a flow of the precursor, and
evacuating the reaction chamber by moving the susceptor into the load/unload chamber.
The memory can be programmed to enable the controller to execute the following steps after ceasing the flow of the precursor:
exposing the substrate to the precursor in the reaction chamber for a soak period; and
after the soak period, evacuating the reaction chamber by moving the susceptor to the load/unload chamber.
Additionally or alternatively, controller 134 can be configured to cause system 100 to automatically perform any of the methods described herein.

As noted above, FIG. 1 illustrates system 100 in a load/unload position. While in this position, valve 124 is in an open position, allowing a substrate to be loaded onto and/or removed from surface 115 of susceptor 114 using robotic or transfer arm 118. Once the substrate is loaded onto the susceptor, valve 124 is closed to seal load/unload chamber 106, and load/unload chamber 106 (and reaction chamber 104) is exposed to vacuum source 116. For example, load/unload chamber 106 can be exposed to vacuum source 116 to bring the pressure within load/unload chamber 106 to about 1 to about 10⁻⁶, about 0.1 to about 10⁻⁴, or about 10⁻² to about 10⁻³ Torr.

After a substrate has been loaded onto susceptor 114, susceptor 114 is raised to a processing position, as illustrated in FIG. 2. In this position, top surface 115 of susceptor 114 forms at least a portion or a bottom of reaction chamber 104. Once the substrate is in the processing position, one or more precursor gasses are flowed across a surface of the substrate. The flow of the precursor(s) can then stop for a soak period. During this period, the partial pressure of one or more precursors and/or absolute pressure within reaction chamber 104 can be maintained at a relatively high level by sealing reaction chamber 104 from load/unload chamber 106. The seal can be formed between a susceptor surface 302 and an interior surface 304 of reaction chamber 104. Surfaces 302 and 304 can be machined and mated (e.g., having linear mated slanted surfaces as illustrated) to provide a substantial seal between reaction chamber 104 and load/unload chamber 106.

Susceptor 114 can then be lowered to purge reaction chamber 104, as illustrated in FIG. 3. Purging of reaction chamber 104 can result, at least in part, from the pressure differential between load/unload chamber 106 and reaction chamber 104 and/or by supplying a purge gas—e.g., from purge gas source 110, though gas distribution apparatus 112.

FIG. 7 illustrates another system 700, in accordance with exemplary embodiments of the disclosure. System 700 is similar to system 100, except system 700 includes a relatively simple inlet port 722, rather than gas distribution apparatus 112. System 700 also includes a reaction chamber 704, which is defined by an upper surface 702 of a reaction chamber, rather than a gas distribution apparatus. This relatively simple design may be easier and/or less expensive to manufacture, relative to system 100. System 700 is also illustrate with liner 740 and a cooler/condenser plate 716, which can be used to getter precursors and/or byproducts during a purge step. Any combination of liner 740 and a cooler/condenser plate 716 could similarly be included in system 100.

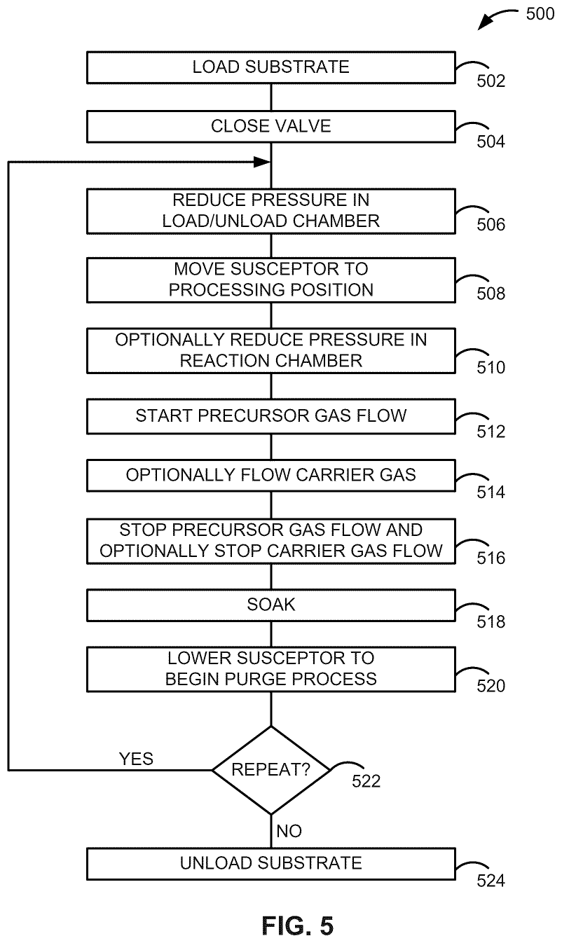

FIG. 5 illustrates a method 500 in accordance with exemplary embodiments of the disclosure. Method 500 includes loading a substrate onto a susceptor (step 502), closing a valve (step 504), reducing a pressure in a load/unload chamber of a reactor (step 506), moving the susceptor to a processing position (step 508), optionally reducing, i.e., further reducing, a pressure within a reaction chamber (step 510), starting a flow of a precursor gas (step 512), optionally flowing a carrier gas (step 514), stopping the flow of the precursor gas and optionally stopping the flow of the carrier gas (step 516), soaking the substrate in the presence of one or more precursors (step 518), lowering the susceptor to begin a purge process (step 520), optionally repeating steps 506-520 for the same or different precursors (step 522), and unloading the substrate (step 524).

During step 502, a valve (e.g., valve 124) is in an open position to allow a substrate to be placed onto a susceptor (e.g., susceptor 114) in a load/unload chamber (e.g., load/unload chamber 106) of a reactor. The valve is then closed during step 504. Once the valve is closed, an inert gas can be provided between the valve or an interior surface of the reactor (e.g., an interior surface of a load/unload chamber) and a protective plate to protect the valve from chemicals used during substrate processing. Alternatively, the gas curtain can be continuously provided between the valve/interior surface and the protective plate, or provided any time before a purge process. After the valve is closed, during step 506, the load/unload chamber, as well as the reaction chamber, can be exposed to a vacuum source (e.g., vacuum source 116) to obtain a desired pressure within the reactor and/or the load/unload chamber. The substrate can then be placed within the reaction chamber by moving the susceptor during step 508, and the reaction chamber can optionally be exposed to the same or a different vacuum source for a period of time during step 510. During step 508 a seal or a substantial seal (e.g., a tortuous path) can be formed between the reaction chamber and the load/unload chamber, such that relatively little gas flows between the chambers. Alternatively, a small space between the reaction chamber and the load/unload chamber can be maintained during a flow-type reaction step that can be performed in addition to or in lieu of the soak step described below. At step 512, one or more precursor gasses are flowed over the substrate surface for a period of time. To facilitate provision of the one or more precursors, heat can be applied to one or more precursors sources and/or a bubbler can be used. A carrier gas can be flowed concurrently with one or more precursor gasses and can mix at mixer 122 and/or a carrier can be mixed with a precursor gas within a precursor source (e.g., source 107, 108). In accordance with some examples of the disclosure, a carrier gas is flowed for only a portion—e.g., the latter half—of the time that a precursor gas is flowed. At step 516, the flow of precursor gas and optionally of any carrier gas is stopped for a soak period (step 518). During the soak period, the reaction chamber may run non-isothermally—e.g., a susceptor can be at one temperature and a top surface of the reaction chamber can be at another temperature, causing the temperature within the reaction chamber to change as precursor, carrier, and/or purge gasses are introduced to the reaction chamber. For example, a temperature of a top surface of the reaction chamber can be higher than the temperature of the susceptor, which can cause a substrate surface to receive heat from the top surface as the susceptor is moved to the processing position. Likewise, the substrate could cool as it is moved away from the top surface. A duration of a soak period (step 518) can vary by application and can range from, for example, about 0.2 to about 600, about 1 to about 60, or about 5 to about 30 seconds. After the soak period, the susceptor is lowered (step 520), such that unreacted precursors and/or reaction byproducts can be purged from the reaction chamber, through the load/unload chamber, and toward the vacuum source. During steps 506-520, the reaction chamber and/or load/unload chamber can continue to be exposed to the vacuum source to facilitate purging of the reaction chamber once the susceptor is moved during step 520. For example, the load/unload chamber can be maintained at a desired pressure during one or more of steps 506-518 or 520. Additionally or alternatively, the reaction chamber can be exposed to a vacuum source prior to moving the susceptor; this has the advantage of keeping the load/unload chamber relatively clean. As illustrated, method 500 can repeat steps 506-520 for the same (e.g., for self-assembled monolayers) or different precursors (e.g., different precursors used in ALD deposition). To facilitate the purging steps, one or more purge gasses can be supplied to the reaction chamber and/or the load/unload chamber. The substrate can then be removed by moving the susceptor to the load/unload position and opening the valve at step 524.

A purging time during step 520 can be relatively short. By way of examples purging times can range from about 0.1 to about 300, about 1 to about 60, or about 2 to about 10 seconds in duration.

It may be desirable to occasionally clean portions of the system, such as the reaction chamber and/or the load/unload chamber. In these cases, the load/unload chamber would generally require less-frequent cleaning than the reaction chamber, because any deposition reactant would be greatly diluted in the load/unload chamber and the residence times of the reacts would likely be much lower. Any exemplary cleaning compound includes NF3.

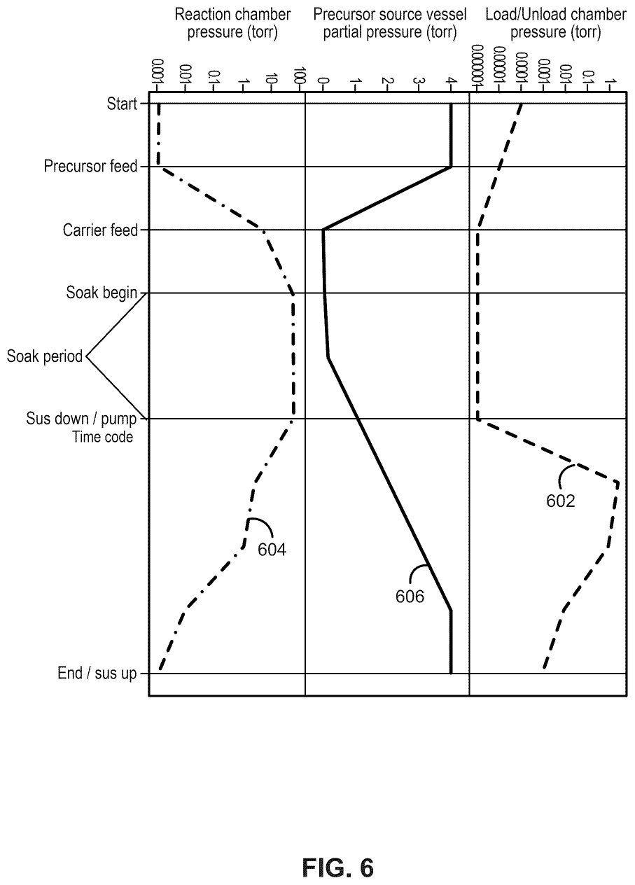

FIG. 6 illustrates a pressure diagram, illustrating exemplary pressures 602 within a load/unload chamber (e.g., load/unload chamber 106), pressures 604 within a reaction chamber (e.g., reaction chamber 104), and pressures 606 within a precursor source vessel during a process. The illustrated process starts once a susceptor is in a processing position. As illustrated, the pressure within the load/unload chamber can decrease at the start of the process and continue to decrease as the precursor is flowed until the pressure reaches a low value). The pressure can remain at or near the low value until a purge process begins, at which time, the pressure rises within the load/unload chamber. Meanwhile the pressure within the reaction chamber can be initially low, and rise as precursor and/or carrier gasses are introduced to the reaction chamber. In the illustrated example, the carrier gas flow begins after the precursor flow begins. The pressure can then remain substantially constant within the reaction chamber during the soak period, and then fall as the substrate is moved from the processing position to a purge position (e.g., as illustrated in FIG. 3). The pressure within the reaction chamber can be further reduced exposing the reaction chamber to a vacuum source after the soak period and before or during a step of moving the susceptor. And, a pressure within a precursor source vessel can be initially high (e.g., as a result of heating the vessel) and lower as the precursor gas is introduced to the reaction chamber. The pressure within the precursor source vessel can then rise again—e.g., when the source precursor is shutoff from the reaction chamber (e.g., at the beginning of a soak period) and/or at the end of the soak period.

As noted above, for some types of reactions, it may be desirable to have a relatively high partial pressure of one or more precursors and/or a high absolute pressure within a reaction chamber. One technique to obtain the desired precursor partial pressures is to heat the precursor source to increase the evaporation rate of the precursor and to increase the saturation vapor pressure of the precursor. Additionally or alternatively, an inert gas pad can be used to increase a pressure within the reaction chamber during a soak period. An exemplary inert gas pad is disclosed in U.S. application Ser. No. 12/763,037, entitled “PRECURSOR DELIVERY SYSTEM,” the contents of which are hereby incorporated herein by reference, to the extent such contents do not conflict with the present disclosure. While use of the gas pad does not necessarily increase a dose of a precursor in the reaction chamber, the total pressure within the reaction can be increased using the gas pad, and thus an amount of gas-surface collisions can be increased using a precursor gas pad.

Although exemplary embodiments of the present disclosure are set forth herein, it should be appreciated that the disclosure is not so limited. For example, although the apparatus and methods are described in connection with various specific components, the disclosure is not necessarily limited to these configurations. Various modifications, variations, and enhancements of the apparatus and methods set forth herein can be made without departing from the spirit and scope of the present disclosure.

What is claimed is:

1. A method comprising the steps of:
moving a susceptor from a load/unload position to a processing position;
while the susceptor is in the processing position,
providing a precursor to a reaction chamber, while evacuating a load/unload chamber; and
ceasing a flow of the precursor for a soak period; and
after the soak period, moving the susceptor into the load/unload chamber to expose the substrate to a second pressure that is lower than the first pressure.

2. The method of claim 1, further comprising opening a valve to receive the substrate, closing the valve to seal the opening and protecting the valve with a protective shield.

3. The method of claim 1, wherein the protective shield comprises external dimensions larger than the valve to cover the valve during the evacuating of the reaction chamber.

4. The method of claim 1, further comprising using a carrier gas during only a portion of the step of providing a precursor.

5. The method of claim 4, wherein the carrier gas does not flow during the soak period.

6. The method of claim 1, wherein a pressure within the reaction chamber during the soak period is greater than a pressure within the load/unload chamber during the soak period.

7. The method of claim 1, wherein a seal is formed between a susceptor surface and an interior surface of the reaction chamber during the soak period.

8. The method of claim 1, wherein a pressure within the reaction chamber during the soak period is substantially constant.

9. The method of claim 1, wherein an amount of the precursor continues to rise for a period of time and then remains substantially constant during the soak period.

10. The method of claim 1, wherein the reaction chamber is isolated from the load/unload chamber during the soak period.

11. The method of claim 1, wherein an amount of the precursor within the reaction chamber rises for a period of time prior to the soak period.

12. The method of claim 1, wherein during the soak period, the reaction chamber operates non-isothermally.

13. The method of claim 1, wherein a pressure within the reaction chamber increases during the soak period.

14. The method of claim 1, wherein a duration of the soak period is between about 1 second and about 60 seconds.

15. The method of claim 1, comprising repeating the steps of moving a susceptor from a load/unload position to a processing position, providing the precursor, and moving the susceptor into the load/unload chamber.

16. The method of claim 1, further comprising, while the susceptor is in the processing position, providing a second precursor to the reaction chamber.

17. The method of claim 1, wherein a tortuous path is formed between the reaction chamber and the load/unload chamber when the substrate is in a processing position.

18. The method of claim 1, further comprising a step of reducing a pressure in the load/unload chamber prior to the step of moving a susceptor from a load/unload position to a processing position.

19. The method of claim 1, further comprising a step of reducing a pressure in the load/unload chamber after the step of moving a susceptor from a load/unload position to a processing position.

20. A method comprising the steps of:
moving a susceptor from a load/unload position to a processing position;
providing a precursor to a reaction chamber while evacuating a load/unload chamber;
ceasing a flow of the precursor and maintaining the susceptor in the processing position for a soak period; and
after the soak period, moving the susceptor into the load/unload chamber to expose the substrate to a second pressure that is lower than the first pressure.
